(19) United States
(12) Patent Application Publication
(10) Pub. No.: US 2012/0103381 A1
(43) Pub. Date: May 3, 2012

(54) Segmented thermoelectric module with bonded legs

(75) Inventors: Frederick A. Leavitt, San Diego, CA (US); John W. McCoy, San Diego, CA (US); Panneerselvam Marudhachalam, Ludwigshafen (DE); Martin Gaertner, Worms (DE)

(73) Assignee: BASF SE and Hi-Z Technology, Inc.

(21) Appl. No.: 13/317,608

(22) Filed: Oct. 24, 2011

Related U.S. Application Data
(63) Continuation-in-part of application No. 12/317,170, filed on Dec. 19, 2008.
Application No. 12/317,170 is a continuation-in-part of application No. 12/590,653, filed on Nov. 12, 2009.

(51) Int. Cl. H01L 35/32; H01L 35/20

(52) U.S. Cl. 136/238

(57) ABSTRACT

A segmented lead telluride egg-crate thermoelectric module. In preferred embodiments N legs and P legs are segmented into at least two segments. The segments are chosen for their figure of merit in the various temperature ranges between the hot side and the cold side of the module. In preferred embodiments a low-temperature egg-crate, molded from a liquid crystal polymer material, having very low thermal conductivity holds in place and provides insulation and electrical connections for the thermoelectric N legs and P legs at the cold side of the module. A castable ceramic capable of operation at temperatures in excess of 500° C. is used to provide electrical insulation between the legs at the hot side of the module.

### CROSS REFERENCE TO RELATED APPLICATIONS

The present invention is a continuation-in-part of Ser. No. 12/317,170 filed Dec. 19, 2008 and Ser. No. 12/590,653, filed Nov. 12, 2009, both of which are incorporated herein by reference.

### FIELD OF THE INVENTION

The present invention relates to thermoelectric modules and especially to mid temperature to high temperature thermoelectric modules.

### BACKGROUND OF THE INVENTION

### Thermoelectric Materials

The Seebeck coefficient of a thermoelectric material is defined as the open circuit voltage produced between two points on a conductor, where a uniform temperature difference of 1 K exists between those points.

The figure-of-merit of a thermoelectric material is defined as:

$$Z = \frac{{α}^{2} σ}{κ} ,$$

where α is the Seebeck coefficient of the material, σ is the electrical conductivity of the material and κ is the total thermal conductivity of the material.

A large number of semiconductor materials were being investigated by the late 1950's and early 1960's, several of which emerged with Z values significantly higher than in metals or metal alloys. As expected no single compound semiconductor evolved that exhibited a uniformly high figure-of-merit over a wide temperature range, so research focused on developing materials with high figure-of-merit values over relatively narrow temperature ranges. Of the great number of materials investigated, those based on bismuth telluride and lead telluride alloys emerged as the best for operating in various temperature ranges up to 600° C. Much research has been done to improve the thermoelectric properties of the above thermoelectric materials. For example n-type Bi₂Te₃ typically contains 5 to 15 percent Bi₂Se₃ and p-type Bi₂Te₃ typically contains 75 to 80 Mol percent Sb₂Te₃. Lead telluride is typically doped with Na and enriched in Te for P type behavior and for N type behavior the lead telluride is typically doped with iodine and enriched in Pb.

### Standard Designations

The temperature at which a thermoelectric alloy is most efficient can usually be shifted to higher or lower temperatures by varying the doping levels and additives. Some of the more common variations with PbTe alloys are designated in the thermoelectric industry as 3N and 2N for N type and 2P and 3P for P type. An in depth discussion of PbTe alloys and their respective doping compositions is given in the book, Thermoelectric Materials and Devices, edited by Cadoff and Miller, Chapter 10 “Lead Telluride Alloys and Junctions.” For further understanding of Bi₂Te₃ based alloys and their doping, see Chapter 9 of the above book and two books edited by D. M. Rowe “CRC Handbook of Thermoelectrics, especially Chapter 19 and Thermoelectrics Handbook “Macro to Nano, Chapter 27. In this specification and in the claims the term PbTe is meant to include any lead and tellurium semi-conductor alloy when both the lead and tellurium Mol percentage is greater than 20 percent. This includes intrinsic or doped N or P type PbTe, PbSnMnTe and PbSnTe alloys, PbTe doped with Thallium, or AgTe₂.

### Temperature Ranges for Best Performance

Thermoelectric materials can be divided into three categories: low, mid-range and high temperature.

### Low Temperature

Commercially available low-temperature materials normally include Bi₂Te₃ alloys. When operated in air, these materials can not exceed 250° C. on a continuous basis without severe deterioration in performance. These alloys are mainly used for cooling although there are a number of waste heat recovery applications based on these Bi₂Te₃ alloys. When used as a power source, Bi₂Te₃ alloys rarely exceed 5% efficiency.

### Mid-Range Temperature

Mid-range materials are normally based on the use of lead telluride, PbTe. PbTe can operate up to about 560° C. Thermoelectric legs comprised primarily of the TAGS group of materials (tellurium, antimony, germanium and silver) provide good performance at about 450° C. Some cobalt based alloys (referred to as skutterudites) are being investigated that also fall into this category but they exhibit high vaporization rates which must be contained for long life. All mid-range thermoelectric alloys known to Applicants will oxidize in air and must be hermetically sealed. Prior art PbTe alloys rarely exceed about 7 percent efficiency. A large number of doping materials are currently being proposed for improvements in performance for all of these mid-range materials.

### High-Temperature—Primarily for Space Applications

High-temperature thermoelectric materials are normally based on SiGe and Zintl alloys and can operate near 1,000° C. Modules based on these alloys are difficult to fabricate, expensive and are normally used only in space applications. These prior art high temperature materials can achieve efficiencies as high as 9 percent in some applications, but to date commercial application of these modules has been rare.

### Segmented Legs

Segmented thermoelectric legs with mid-temperature to high-temperature materials on the hot side of the leg and a low temperature material on the cold side of the legs can significantly improve performance.

Some of the higher temperature thermoelectric materials tend to experience high free vaporization rates (such as 50% loss in 300 hours). These modules can be sealed in a metal package referred to as a can. The process is called canning. Alternately, one fabricator has contained the material in aerogel insulation in an attempt to suppress the evaporation. In another vapor suppression approach, the sample was coated with 10 μm of titanium. Metal coatings can produce electrical and thermal shorting.

### Thermoelectric Modules

Thermoelectric power production is typically accomplished with a number of thermoelectric modules sandwiched between a hot surface and a cold surface. These modules produce electricity directly from a temperature differential utilizing the thermoelectric effect. The modules typically include P-type thermoelectric semiconductor elements and N-type thermoelectric semiconductor elements. These thermoelectric elements are called N legs and P legs. The effect is that a voltage differential of a few millivolts is created in each leg in the presence of a temperature difference of a few hundred degrees. Since the voltage differential is small, many of these legs (such as about 100 legs in each module) are typically positioned side-by-side between the hot surface and the cold surface but are connected electrically in series to produce open circuit potentials of a few volts and power output in the range of a few watts per module. A large number of these modules can be combined to produce power in the kilowatt range from a heat source such as the exhaust system of a truck. Thermoelectric modules are well suited to recover energy from a variety of waste heat applications because they are:

| | | |
|---|---|---|
| Small | Easily scaled up or down | Solid state |
| Highly reliable | Silent | Potentially cost effective |

### Hi-Z Prior Art Bismuth Telluride Molded Egg-Crate Modules

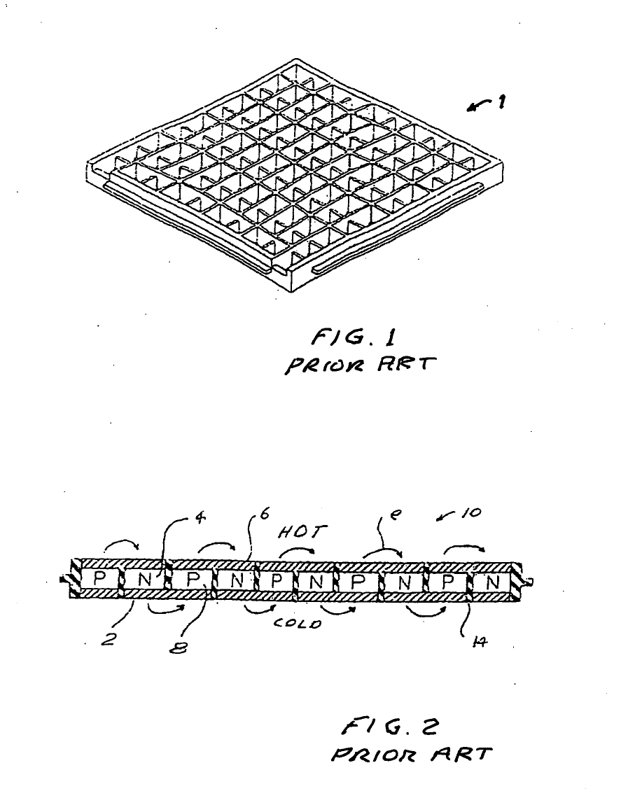

For example Hi-Z Technology, Inc., with offices in San Diego Calif., offers a Model HZ-14 thermoelectric bismuth telluride thermoelectric module designed to produce about 14 watts at a load potential of 1.66 volts with a 200° C. temperature differential. Its open circuit potential is about 3.5 volts. The module contains 49 N legs and 49 P legs connected electrically in series. It is a 0.5 cm thick square module with 6.27 cm sides. The legs are P-type and N-type bismuth telluride semiconductor legs and are positioned in an egg-crate type structure that insulates the legs from each other except where they are intentionally connected in series at the top and bottom surfaces of the module. That egg-crate structure which has spaces for the 98 active legs is described in U.S. Pat. No. 5,875,098 which is hereby incorporated herein by reference. The egg-crate is injection molded in a process described in detail in the '098 patent. This egg-crate has greatly reduced the fabrication cost of these modules and improved performance for reasons explained in the patent. FIG. 1 is a drawing of the egg-crate and FIG. 2 is a cross sectional drawing of a portion of the egg-crate showing how the P-legs and N-legs are connected in series in the egg-crate. The curved arrows e show the direction of electron flow through top conductors 2, N legs 4, bottom conductors 6, and P legs 8 in this portion 10 of the module. Insulating walls 14 keep the electrons flowing in the desired series circuit. Other Bi₂Te₃ thermoelectric modules that are available at Hi-Z are designed to produce 2.5 watts, 9 watts, 14 watts and 20 watts at the 200° C. temperature differential as explained above. The term bismuth telluride is often used in the thermoelectric industry to refer to all combinations of Bi₂Te₃, Bi₂Se₃, Sb₂Te₃ and Sb₂Se₃. (This apparently is because antimony is chemically similar to bismuth and selenium is chemically similar to tellurium.) In this document where the term Bi₂Te₃ is used, it means any combination of Bi₂Te₃, Bi₂Se₃, Sb₂Te₃ and Sb₂Se₃.

### Temperature Limitations

The egg-crates for the above described Bi₂Te₃ modules are injection molded using a thermoplastic supplied by Dupont under the trade name “Zenite”. Zenite melts at a temperature of about 350° C. The thermoelectric properties of Bi₂Te₃ peak at about 100° C. and are greatly reduced at about 250° C. For both of these reasons, uses of these modules are limited to applications where the hot side temperatures are lower than about 250° C.

### Thermoelectric Materials

### Figures of Merit

### Thermoelectric Materials

Many different thermoelectric materials are available. These include bismuth telluride, lead telluride, silicon germanium, silicon carbide, boron carbide and many others. In these materials relative abundance and doping ranges can make huge differences in the thermoelectric properties. Much experimental data regarding these materials and their properties is available in the thermoelectric literature such as the CRC Handbook referenced above. Each of these materials is rated by their “figure of merit” (Z) which in all cases is very temperature dependent. Despite the fact that there exists a great need for non-polluting electric power and the fact that there exists a very wide variety of un-tapped heat sources; thermoelectric electric power generation in the United States and other countries is minimal as compared to other sources of electric power. The reason primarily is that thermoelectric efficiencies are typically low compared to other technologies for electric power generation and the cost of thermoelectric systems per watt generated is relatively high compared to other power generating sources. Generally the efficiencies of thermoelectric power generating systems are in the range of about 5 percent.

### Lead Telluride Modules

Lead telluride thermoelectric modules are also known in the prior art. A prior art example is the PbTe thermoelectric module described in U.S. Pat. No. 4,611,089 issued many years ago to two of the present inventors. This patent is hereby incorporated herein by reference. That module utilized lead telluride thermoelectric alloys with an excess of lead for the N legs and lead telluride with an excess of tellurium for the P legs. Performance can be improved with doping using known techniques. The thermoelectric properties of heavily doped lead telluride thermoelectric alloys peak in the range of about 425° C. The egg-crate for the module described in the above patent was fabricated using a technique similar to the technique used many years ago for making chicken egg crates using cardboard spacers. For the thermoelectric egg-crate the spacers were mica which was selected for its electrical insulating properties at high temperatures. Mica, however, is marginal in strength and cracks easily. A more rugged high-temperature material is needed.

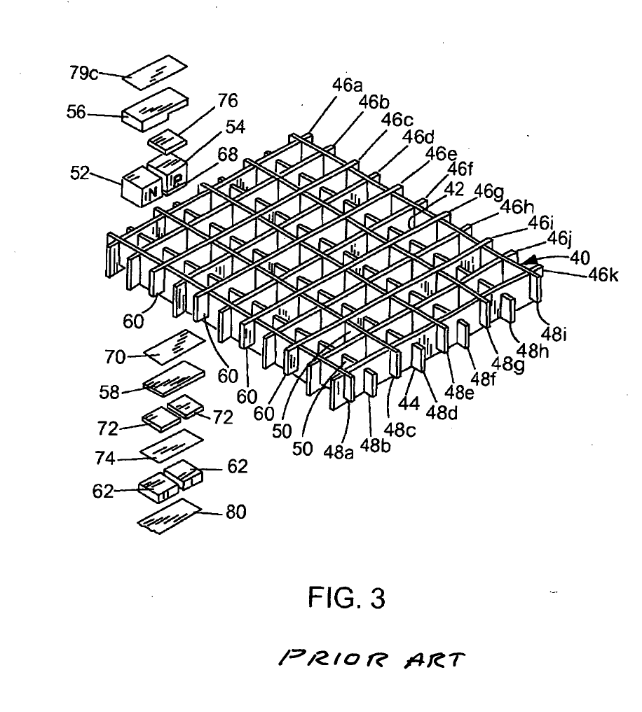

FIG. 3 is a drawing from the U.S. Pat. No. 4,611,089 showing a blow-up of the module described in that patent. The egg-crate included a first set of parallel spacers 46a to 46k and a second set of spacers 48a to 48i. The N legs are shown at 52 and the P legs are shown at 54. The module included hot side conductors 56 and cold side conductors 58 to connect the legs in series as in the Bi₂Te₃ module described above.

That lead telluride module was suited for operation in temperature ranges in excess of 500° C. But the cost of fabrication of this prior art module is greatly in excess of the bismuth telluride module described above. Also, after a period of operation of about 1000 hours some evaporation of the P legs and the N legs at the hot side would produce cross contamination of all of the legs which would result in degraded performance. Prior art thermoelectric modules have required special compression techniques applied to the modules to assure good electrical contacts with respect to the various segments of the thermoelectric legs.

What is needed is a fully bonded, low-cost, mid to high-temperature, high-efficiency thermoelectric module designed for operation at hot side temperatures in the range of 500° C. or higher preferably with thermoelectric properties substantially in excess of prior art high-temperature thermoelectric modules.

### SUMMARY OF THE INVENTION

The present invention provides a fully bonded, segmented, long-life, low-cost, mid-temperature to high-temperature, high-efficiency thermoelectric module. Preferred embodiments include a multi-segment, egg-crate module with N legs and P legs that are segmented into at least two segments of thermoelectric materials. In preferred embodiments the segments are chosen for their figure of merit in the various temperature ranges between the hot side and the cold side of the module. In preferred embodiments a low-temperature egg-crate, molded from a liquid crystal polymer material, having relatively very low thermal conductivity holds the legs in place and provides insulation and permits electrical connections for the thermoelectric N legs and P legs to be efficiently applied at the cold side of the module. A castable ceramic capable of operation at temperatures in excess of 500° C. is used to provide electrical insulation between the legs at the hot side of the module. In preferred embodiments the high-temperature ceramic is Resbond 989 or Resbond 908 which is available as a high-temperature, general purpose ceramic adhesive from Cotronix Corporation, and the liquid crystal polymer material is Zenite available from DuPont in the form of a liquid crystal polymer resin. In preferred embodiments the module is sealed in an insulating capsule or a number of modules are sealed together in a thermoelectric generator. All of the parts of the module a solidly bonded together is the preferred module fabrication process so that external pressure is not necessary to assure good contacts within the module.

In a preferred embodiment the N legs are comprised of two types of PbTe and the P legs are comprised of PbTe on the hot side and BiTe on the cold side. To fabricate the legs for this preferred embodiment, iron contacts are vacuum hot pressed along with the thermoelectric materials to create good compatible contact surfaces. Interfaces between the materials are graduated to improve performance. Special techniques are utilized to assure fines are removed. A thin copper binding layer is also added on top of the iron at the hot side of the legs and hot pressed into the leg material. A dual egg-crate is provided with high temperature ceramic used at the hot side and low thermal conductivity moldable thermo plastic is used for the cold side. To fabricate the legs a molybdenum sulfide lubricant is applied to all surfaces of the hot pressing die and plungers to minimize or eliminate leg damage during removal from the die. Tungsten or molybdenum disulfide could also be used as the lubricant.

In preferred embodiments the hot and middle segments for the N legs are two or three types of lead telluride thermoelectric material (3N and/or 2N) and the low-temperature material is bismuth telluride. The hot and middle segments for the P legs are also lead telluride (3P and/or 2P, respectively). And the low-temperature material again is bismuth telluride. In preferred embodiments low-temperature contacts are provided by thermally sprayed a thermal spray metalizing process using a molybdenum bonding layer and an aluminum top layer or a single layer of zinc, either of which provides excellent electrical contacts between the N and P legs.

The two or three segment legs are produced using a vacuum hot pressed powder metallurgy process in which the leg materials are added to a multi-cavity molybdenum die and hot pressed simultaneously. First a thin layer of iron powder is inserted into the cavity. Then the two or three thermoelectric materials are sequentially added. Iron metal powder is then mixed with lead telluride powder and added at the hot end of each of the P and N legs to provide a one millimeter thick graded layer of PbTe and iron powder. On top of the graded layer a thin layer of 100 percent iron metal layer of powder is added to form the top of the legs. Then the leg powders are then hot pressed at 7,000 psi and 600° C. The iron layer at the top of the legs chemically isolates the PbTe from a copper layer which is added during a centering step following the hot press. The purpose of the thin copper layer is to aid in the bonding of a copper conductor which connects the N and P legs at the hot side electrically in series.

The hot end of each leg is capped with a copper segment added to enable solid-state diffusion monding to a copper “jumper” or “hotshoe” placed above it that bridges between pairs of legs in the module providing electrical connections. The copper segment is formed from a copper foil, and is bonded and integrate into the rest of the leg during the same hot pressing and sintering operation that densifies the PbTe and Bi₂Te₃ powders. A reaction-barrier layer of iron is disposed between the copper and PbTe segments to prevent diffusion of copper into PbTe and the consequent formation of CuTe. The iron layer is formed from iron powder densified during the hot-pressing and sintering operation.

### Special Cold Side Contacts

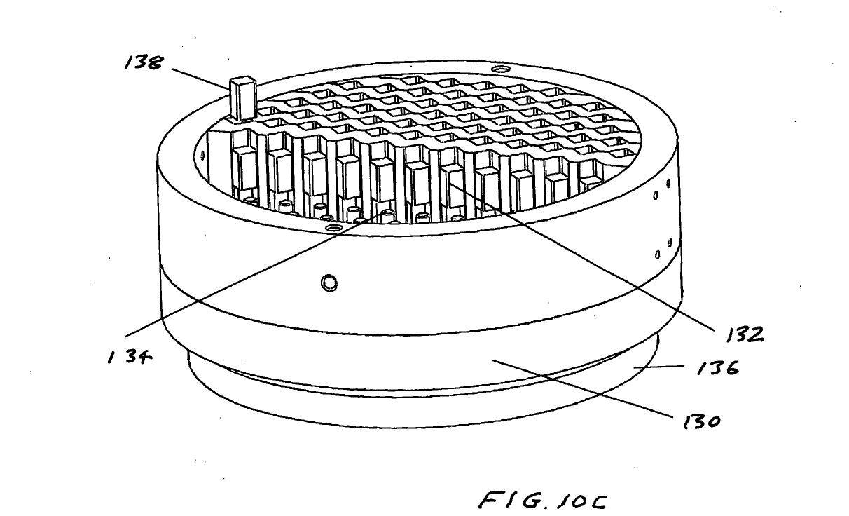

With a Bi₂Te₃ segment on the cold side of the PbTe leg it is possible to use Applicants' employer's standard prior art Bi₂Te₃ contacting methods as described in U.S. Pat. No. 5,856,200, especially FIGS. 19A and 19B and related text, which is incorporated by reference herein. This method is a method of forming contacts to Bi₂Te₃ using metallic thermal spraying process. The resultant cold side contact is firmly bonded to the legs and eliminates the need to make numerous individual electrical connections. Preferred metallization schemes include: (1) pure zinc, (2) a two-layer system using pure molybdenum as a bond coating and pure aluminum as the electrical and thermal conductor layer.

### Multi-Cavity Molybdenum Die

In preferred embodiments the legs are formed by placing the appropriate layers of the powder in a multi-cavity molybdenum die with each cavity forming the desired geometry. To allow the parts to be removed without damaging them the die is designed to be disassembled in such a way that the individual legs can be removed with out being subject to undue forces.

### BRIEF DESCRIPTION OF THE DRAWINGS

FIG. 1 is a drawing of a prior art egg-crate for a thermoelectric module.

FIG. 2 is a drawing of a portion of a module with the FIG. 1 egg-crate.

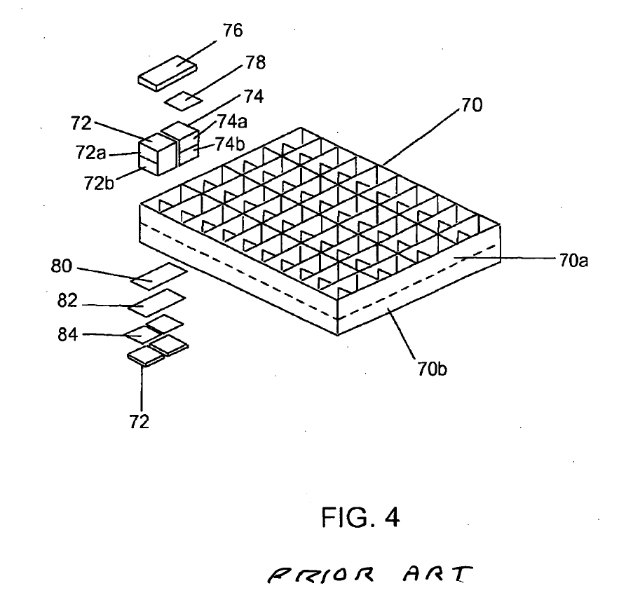

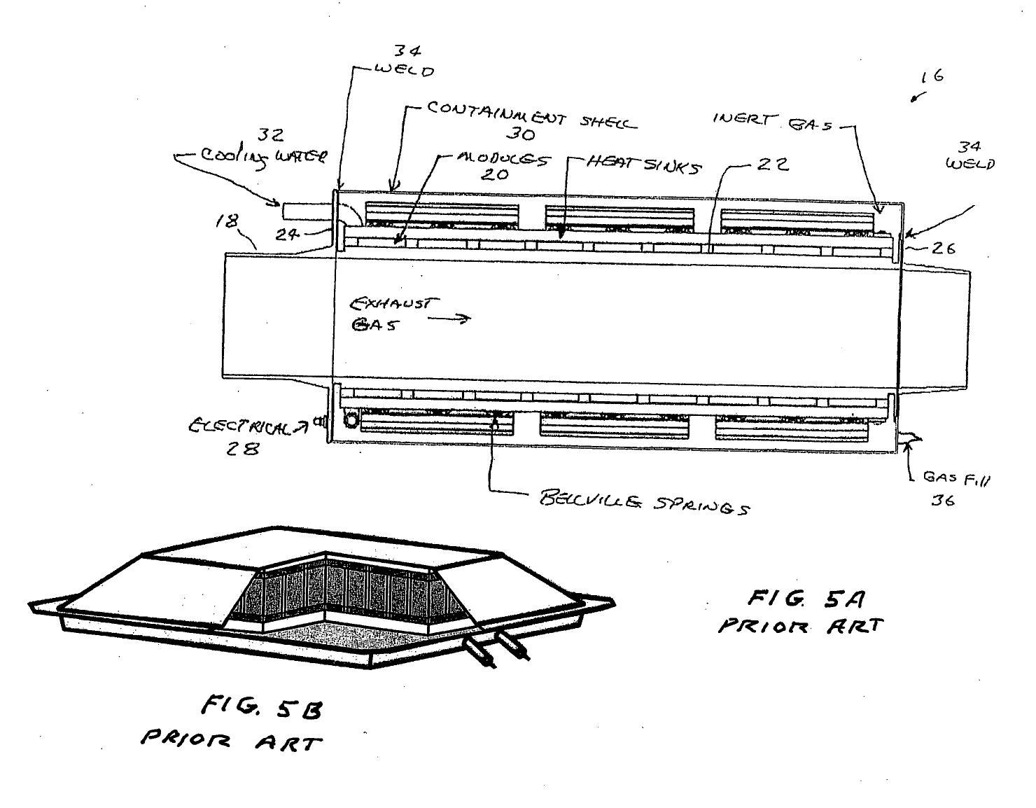

FIGS. 3 and 4 are prior art blown-up drawing of a prior art lead telluride thermoelectric module.

FIG. 5A is a prior art drawing showing an application used to generate electricity from the exhaust gas of a truck.

FIG. 5B shows an encapsulated module.

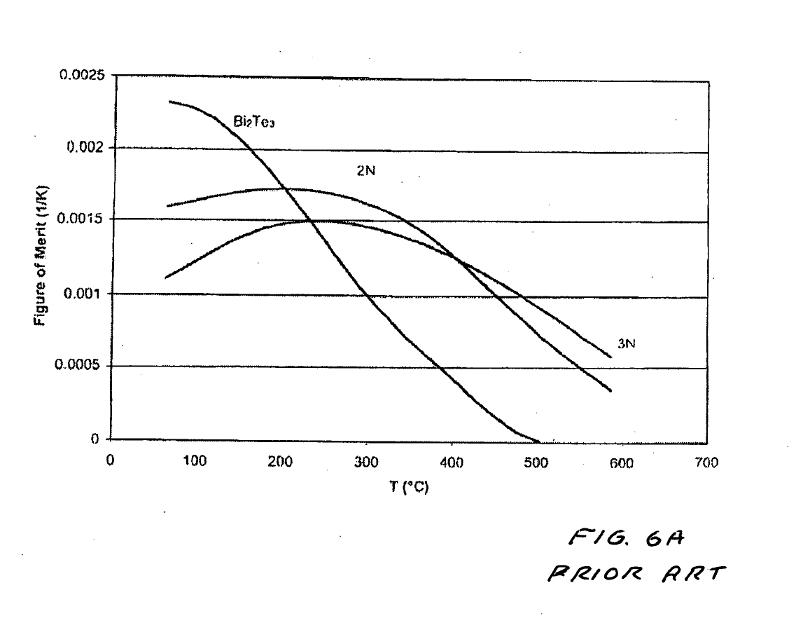

FIGS. 6A and 6B are graphs showing figures of merit for 2N, 3N, 2P and 3P lead telluride thermoelectric material and N and P bismuth telluride material.

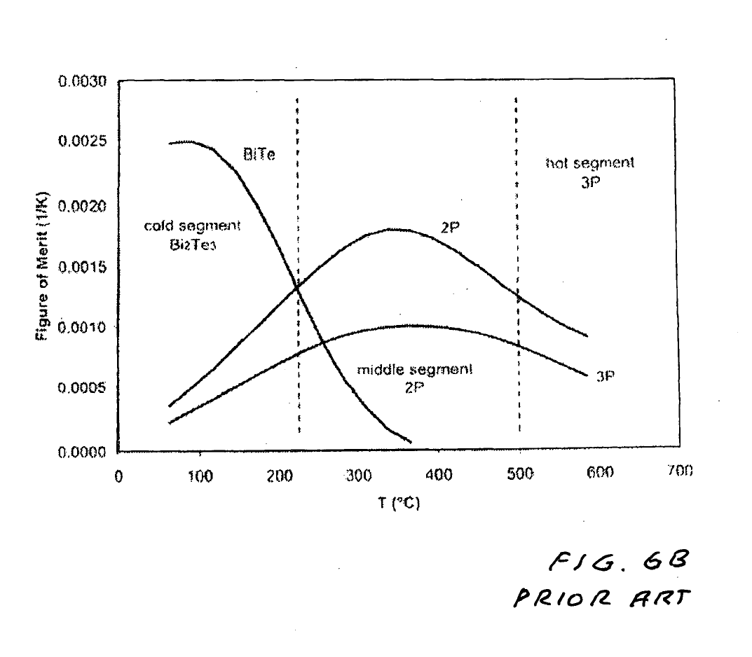

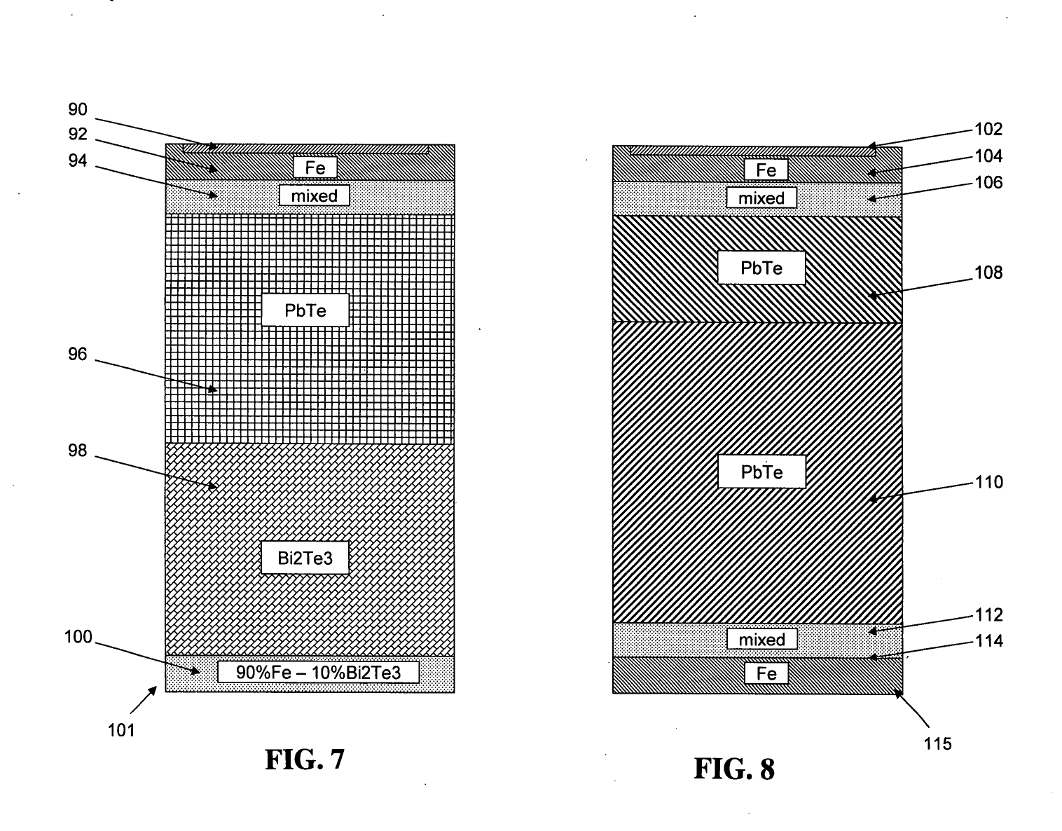

FIG. 7 is a drawing of a P leg in a preferred embodiment.

FIG. 8 is a drawing of an N leg in a preferred embodiment.

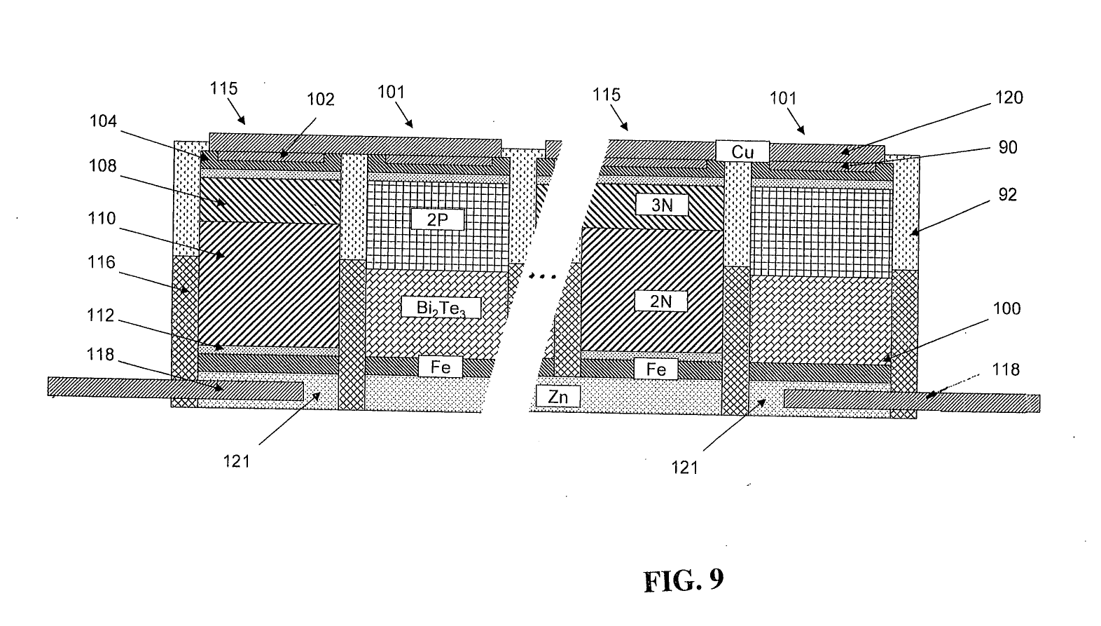

FIG. 9 shows features of a preferred module in accordance with the present invention.

FIGS. 10A, 10B and 10C are drawing showing how the legs are assembled for hot pressing.

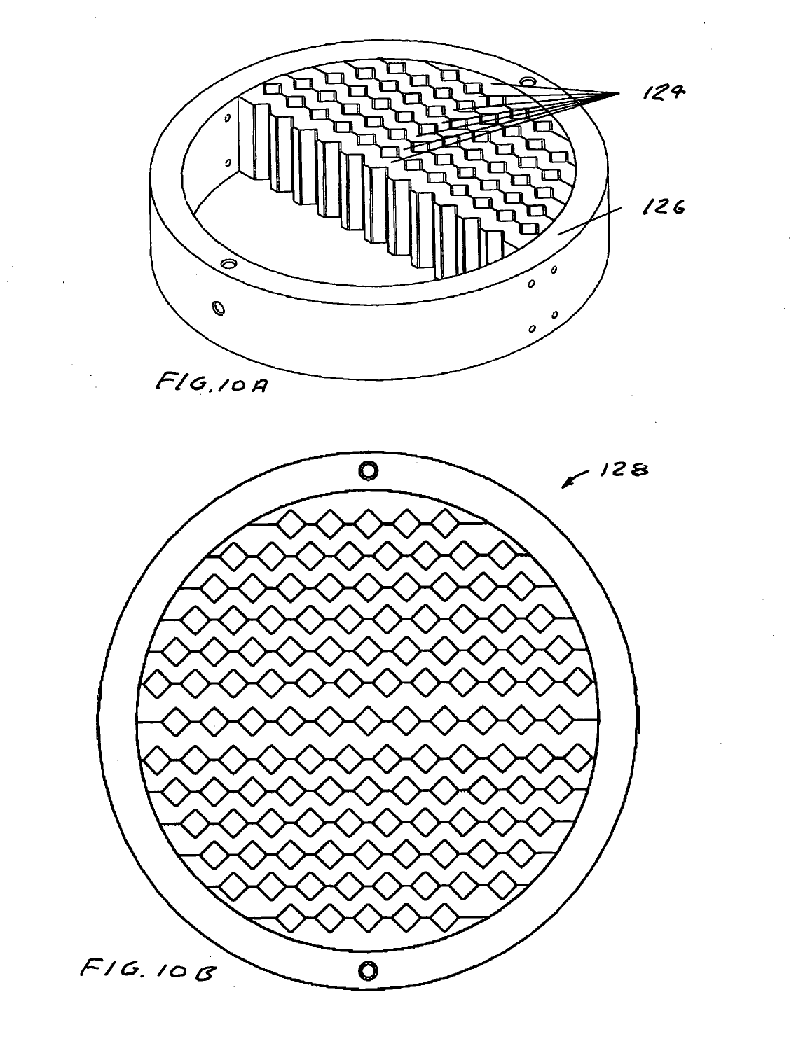

FIG. 11 shows a design of a thermoelectric generator for utilizing the modules for electricity production.

### DETAILED DESCRIPTION OF PREFERRED EMBODIMENTS

### Lead Telluride and Bismuth Telluride

Lead Telluride thermoelectric materials permit the design of thermoelectric modules that can operate more efficiently at higher temperatures as compared to modules based on bismuth telluride alloys. Unlike bismuth telluride however, lead telluride is less ductile and cracks more readily than does bismuth telluride. This makes it difficult to build a bonded module and so lead telluride modules are typically made by assembling many individual components that are subsequently held in compression with pressures as high as 1,000 psi. The high compressive force causes a bond to form between the lead telluride and the contact materials at operating temperatures, but these bonds tend to break when the modules cools. The present invention provides a method of forming permanent bonds on both the hot and cold side of the module which eliminates the need for high compressive forces and permits thermally cycling without the substantial risk of breakage. Details are provided in the sections that follow.

Bismuth telluride works best at temperatures below about 250° C. Bismuth telluride thermoelectric material is available form Marlow Industries with offices in Dallas, Tex. The bismuth telluride segments are preferably doped with 0.1 Mol percent iodoform (CHl₃) to create the low temperature N-type material and 0.1 part per million Pb to create lower temperature P-type material. Several successful methods are available for fabrication of PbTe materials and are described in “Lead Telluride Alloys and Junctions” of Thermoelectric Materials and Devices, Cadoff and Miller, published by Reinhold Publishing Corporation of New York.

Several successful methods are available for making PbTe thermoelectric materials. In a preferred technique appropriate amounts of raw materials are weighed out, mixed and sealed in a quartz tube with an inert atmosphere such as argon. The tube is then heated to 900° C. for 90 minutes and allowed to cool. The resultant ingot is then ground to a −20 mesh powder and lubricated with 0.15 weight percent graphite powder. The powder can then be processed into thermoelectric legs as described in various sections of this specification.

Performance of the lead telluride thermoelectric material at various temperatures depends on the ratio of lead to telluride and also additional materials that can be added to improve performance. Applicants refer to various combinations as 2P, 3P, 2N and 3N lead telluride. Performance of these lead telluride materials as a function of temperature are shown in FIGS. 6A and 6B. In this specification these lead telluride combinations are defined as follows:

| | | | |
|---|---|---|---|
| 2P | lead | 49.5 | mol % |
| | Tellurium | 50.25 | mol % |
| | Na2Te | 0.25 | mol % |
| 3P | lead | 19.74 | mol % |
| | Tellurium | 49.61 | mol % |
| | Tin | 26.93 | mol % |
| | Manganese | 3.47 | mol % |
| | Na2Te | 0.25 | mol % |
| 2N | lead | 50.1 | mol % |
| | Tellurium | 49.98 | mol % |
| | PbI2 | 0.014 | mol % |
| 3N | lead | 50.00 | mol % |
| | Tellurium | 49.972 | mol % |
| | PbI2 | 0.028 | mol % |

### First Preferred Embodiment

A first preferred embodiment can be described by reference to FIGS. 7 through 10C. FIG. 7 shows a P leg of this first preferred embodiment. At the top is a copper layer 90 on the hot end to aid in bonding to a copper conductor. Below copper layer 90 is an iron layer 92 to and a mixed layer 94 of 25 percent Fe and 75 percent P-type PbTe to chemically insulate the PbTe layer 96 from the copper layer 90. Below the PbTe layer 96 is a Bi₂Te₃ layer 98 and at the bottom is a thin layer of Fe 100 to enhance bonds with a later to be provided sprayed zinc connections. The thermoelectric material for layers 96 and 98 are chosen to provide high thermoelectric efficiencies at both the higher and lower temperature regions of the P leg. FIG. 8 shows a similar design for the N legs. At the top is a copper layer 102 and Fe and mixed layers 104 and 106 as for the P leg. The 3N layer 108 is a layer of PbTe designed for high efficiencies at temperatures close to 500° C. and the 2N 110 is a layer of PbTe designed for high efficiencies at temperatures in the range below about 450° C. At the bottom of the N leg 115 is a mixed layer 112 similar to the one at the top and a layer of iron 114 similar to the iron layer at the top.

FIG. 9 shows a section of four legs of a completed module according to this first preferred embodiment showing how the module is constructed. The drawing shows two n legs 115 and two P legs 101. The hot segment 108 of the N leg has been doped to be more efficient at higher temperatures and the cold segment of the N leg has been doped for higher efficiencies at lower temperatures. Iron powder 104 and has been placed at both ends of the N and P legs to act as a diffusion barrier between the thermoelectric materials and the copper and zinc contacts.

A liquid polymer egg-crate 116 holds the legs in place and defines the pattern for the cold side of the module. Copper wire 118 is soldered into the Zn cold junctions 121 to provide the high and low voltage contacts for the module. This drawing shows only portions of four legs. A typical module would contain about 100 legs. Copper layers 90 and 102 provide a surface suitable for diffusion bonding to copper junctions 120 at the hot side of the module connecting all of the legs electrically in series. Empty spaces on the hot side of the module are filled with castable ceramic to inhibit sublimation of PbTe. The ceramic also assures low thermal conductivity and adds strength to the module.

### Iron Contact Surfaces

Very few materials are compatible with PbTe. Many materials that are compatible are not ideal due to their thermal expansion coefficients, electrical conductivity, formability and cost. One of the few materials that is compatible with PbTe is iron so a layer of Fe about one millimeter thick is formed on the hot end of the Bi2Te3-PbTe legs. In preferred embodiments Applicants also add a thin layer of iron mixed with 10 percent Bi₂Te₃ to act as a binder and strengthen the segment at the cold end of the legs. Once in place the contact materials can then be bonded to the Fe surface without worrying about compromising the PbTe.

### Graduated Interface

Fe has a thermal expansion coefficient of 11.8×10⁻⁶ K⁻¹ and PbTe has a thermal expansion coefficient of about 18×10⁻⁶ K⁻¹. This difference causes a stress to form at the Fe/PbTe interface when the leg is heated to its operating temperature of 575° C. The stress that forms will occasionally cause small micro-cracks to form in the P leg since it is less ductile than the N leg. The micro-cracks will sometimes show up as a high resistance in the finished legs. To alleviate the stresses caused by the difference in thermal expansion a thin layer of transition material about 1 mm thick is placed between the Fe layer and the PbTe leg. The transition material consists of 75% PbTe and 25% Fe powders by weight. The PbTe material is ground to a −40 mesh powder and the Fe is a −325 mesh powder. The two powders are mixed by tumbling for one hour. This is often referred to as a “functionally-graded interface”.

### Vacuum Hot Pressed Legs

To form a strong, low resistance bond (less than 10 μΩ) between the Fe layer, the graduated layer and the PbTe layers it is very desirable to simultaneously press the layers together while in a vacuum and heat to 600° C.). Acceptable results are obtained with a 10 μm vacuum, 7,000 psi and 600° C. held for one hour. This preferably can also be done at 500° C. and 6,000 psi for two hours or more.

### Multi-Cavity Molybdenum Die

The legs are formed by placing the appropriate layers of the powder in a multi-cavity die with each cavity forming the desired geometry. To allow the parts to be removed without damaging them the die is designed to be disassembled in such a way that the individual legs can be removed with out being subject to undue forces. It is necessary for the die to be fabricated from a material that is compatible with the PbTe and still capable of withstanding high stresses at 600° C. Some candidate materials are high-temperature iron nickel chrome alloys such as A286, or from pure Molybdenum metal, or from a tungsten carbide/cobalt cermet or from graphite, or from H13 tool steel. In preferred embodiments Applicants have fabricated a multi-cavity die from molybdenum. FIGS. 10A, 160 and 10C show the components of the die and how it is assembled and utilized in the hot pressing process.

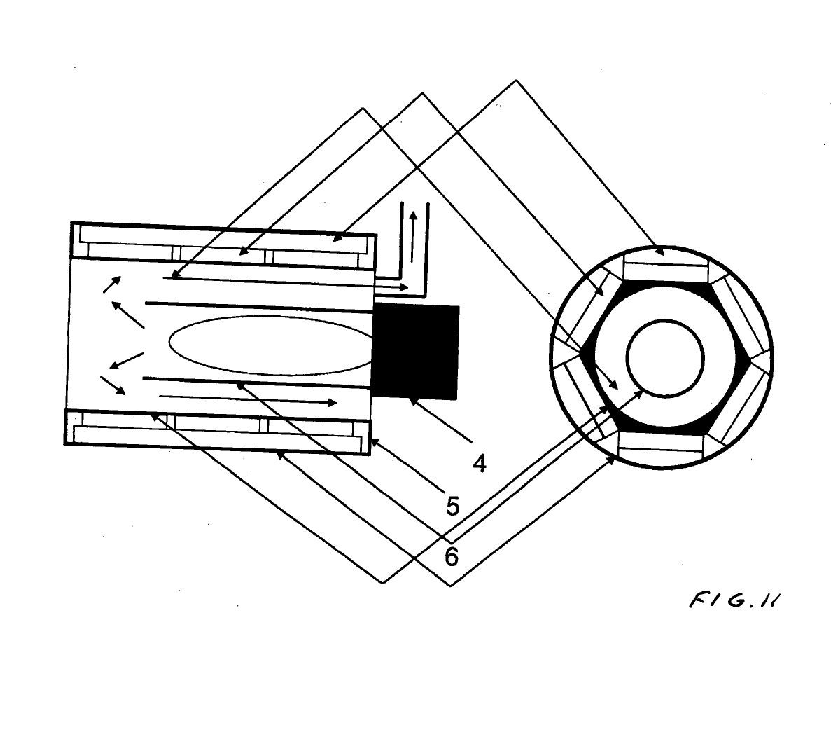

As shown in FIG. 10A the molybdenum die consists of walls 201 and die ring 202. When fully assembled as shown in FIGS. 10A and 10B, 121 cavities are created in the assembly. The dimensions of each of the cavities are 5 mm×5 mm×7 mm. To keep the die walls from falling out the bottom of die assembly 128, a bottom plate 130 with 121 matching pin holes is positioned below the die assembly. All parts of the assembly are sprayed with tungsten disulfide to assure good lubrication and no sticking of the leg material to the assembly parts. The dies fabricated from Mo have demonstrated good results. Molybdenum is much stronger and tougher than graphite, does not deform or creep after prolonged exposure to stress at elevated temperature, and it does not suffer “galling” as does A286 or any stainless steel.

### Creating a Segmented Leg

To form a leg that consists of multiple segments or layers a bottom punch is first inserted into the die described above. The punch is held at the desired depth below the surface of the die by a set of pins inserted into the die cavity from the bottom of the die. The pins are held in position by a pin plate into which they have been inserted. The desired powder is then placed into the die cavities and scraped off so as to be level with the surface of the die. A spacer is then placed between the bottom of the die and the plate that holds the pins that support the bottom punch. With the spacer in between the pin plate and the die the bottom punch and powder already placed into the die are allowed to fall to a lower level. The first charge of powder is then compressed so that the space between the top of the powder and the top of the die is the desired distance and the empty space in the die is filled with the second powder that is to form the second segment of the leg. This process is repeated for each of the desired segments. Once the die is filled with the correct amount of powder in the correct positions the bottom die is allowed to drop to the bottom of the die and a top punch is inserted. Spacers are used to allow the bottom punch to extend below the bottom of the die until the die is placed into the press. Once a small amount of pressure is applied to the loaded die to keep the die and punches in position the spacers are removed. It is desirable to have both the bottom and the top punches extending outside the die so that pressure is applied from both the top and bottom punches. This is referred to as a double acting press and results in more homogeneous density within the leg. The length of the punches and the volume of powder placed into the die is designed to reach maximum density when the surface of the punch comes level with the surface of the die. This results in legs that are all the same length thereby minimizing variation in the length of the legs. The precise procedures for fabricating N legs and P legs for a preferred embodiment shown in FIGS. 7, 8 and 9 are described below with reference to FIG. 10C.

### General Procedure for Loading Powders

In order to provide the desired volume of powder of each layer of the thermoelectric legs, lower punches 132 are inserted into the die and held at desired heights by punch pins 134 fastened to pin plate 136. The pins are inserted through the holes in bottom plate 130. The pins and the plate are standard components of commercially available punch presses. The pins are adjusted to an appropriate position to create a cavity of a desired height in the die assembly for a layer of the thermoelectric legs being fabricated. Then powder for that layer is placed on top of the assembly and allowed to fill the created cavity. Then excess powder is scrapped off. The pins are then lowered leaving a new cavity in the assembly. Then powder for the next layer is placed on top of the assembly and the process is repeated until the powder for all of the layers of the legs have been inserted in the die assembly. Then pins are lowered and the top punches 207 are placed in the cavities after which the pin plate is removed. The loaded die assembly is then placed in a vacuum hot press.

### N Legs

Table I describes the step-by-step process of loading the die assembly for the N legs. The materials used are: PbTe powder, Fe powder, (99.9%−220+325 mesh) mixed Cu foil and WS₂ lubricant. The mixed powder is 75 percent 2N PbTe and 25 percent Fe. Punch positions are adjusted with spacers placed below the pen plate 136. The height of the spacers are provided in parentheses in the table.

TABLE I
Die Assembly Loading Process for N Legs

| | |
|---|---|
| Step 1 | Assemble die, coat all parts with WS₂ and insert walls into ring. |
| Step 2 | Place a bottom punch in each cavity. |
| Step 3 | Drop the punches 2.0 mm and fill all cavities with the mixed |
| | Fe powder. (1.5 mm spacer) |
| Step 4 | Drop the punches an additional 1.0 mm and fill with 0.75, |
| | 2N/0.25Fe mixed powder. (2.5 mm spacer) |
| Step 5 | Drop the punches 9.0 mm and push them to the bottom of the |
| | die. Fill with 2N powder. (11.5 mm spacer) |
| Step 6 | Compact the powder 1.5 mm and fill with 0.75, 2N/0.25Fe |
| | mixed powder. (11.5 mm spacer) |
| Step 7 | Compact the powder 2.0 mm and fill with mixed Fe powder. |
| | (11.5 mm spacer) |
| Step 8 | Compress the powder and place a 4.5 × 4.5 × 0.5 mm piece |
| | of copper on top the Fe powder. (14.0 mm spacer) |
| Step 9 | Force the punches (and the powder) to the bottom of the die |
| | taking care to ensure no Fe powder ends up on top of the |
| | copper. Use a lightly magnetic set of tweezers to remove any |
| | Fe that does get on top of the copper. Be sure that the Fe |
| | underneath the Cu is not disturbed. Add the top punches. |

### Compressing the Powder for the N Legs

After the die assembly has been loaded with powder, the loaded die assembly is loaded into a hot press and 1,000 pounds of force is applied. A thermocouple is then inserted into the die assembly. While cold, a vacuum of about 10 microns is pulled and the hot press is backfilled with argon mixed with 5 percent H₂ to a 10 inch vacuum. These two steps are repeated two more times. The die is heated to 600° C. A vacuum of less than 200 microns is pulled and the chamber is backfilled with the argon mixture to 10 inches. These two steps are repeated two more times. A vacuum of about 10 microns is pulled. The force on each leg is then increased to about 250 pounds. For the 121 legs this will require of total force of about 30,250 pounds. The force is held for 15 minutes. The chamber is then backfilled with the argon mixture to 10 inches vacuum. The temperature and force is held at 600° C. and 250 pounds per leg (about 6,000 psi) for one hour. The load is then reduced to 500 pounds and the chamber is cooled to below 50° C. and the parts are removed.

### P Legs

Table 2 describes the step-by-step process of loading the die assembly for the P legs. The materials used are: PbTe powder, Bi₂Te₃ powder ground to −45 mesh, Fe powder, 99.9%−220+325 mesh, mixed (75 percent Pb and 25 percent Fe) and WS₂ lubricant. Punch positions are adjusted with spacers placed below the pin plate 206. The height of the spacers is provided in parentheses in the table.

TABLE 2
Die Assembly Loading Process for P Legs

| | |
|---|---|
| Step 1 | Assemble die, coat all parts with WS₂ and insert walls into ring. |
| Step 2 | Place a bottom punch in each cavity. |
| Step 3 | Drop punches 2.0 mm and fill all cavities with the mixed |
| | Fe powder mixed with 10% Bi₂Te₃ powder. (1.5 mm spacer) |
| Step 4 | Drop punches an additional 5.5 mm and fill with Bi₂Te₃ |
| | powder. (7.0 mm spacer) |
| Step 5 | Compress the powder and fill with BP powder. |
| | (10.0 mm spacer) |
| Step 6 | Compress the powder and fill with 0.75BP/0.25Fe |
| | mixed powder. (11.0 mm spacer) |
| Step 7 | Compact the powder 3.0 mm and fill with mixed Fe powder. |
| | (13.5 mm spacer) |
| Step 8 | Compress the powder and place a 4.5 × 4.5 × 0.5 mm piece |
| | of copper on top of the Fe powder. (14.0 mm spacer) |
| Step 9 | Force the punches (and the powder) to the bottom of the die |
| | taking care to ensure no Fe powder ends up on top of the |
| | copper. Use a lightly magnetic set of tweezers to remove any |
| | Fe that does get on top of the copper. Be sure that the Fe |
| | underneath the Cu is not disturbed. Add the top punches. |

### Compressing the Powders for the P Legs

The process for compressing the powders for the P legs is the same as the process for the N legs except the peak temperature is limited to 500° C.

### Removal of Fines

When using the die to fabricate thermoelectric legs it is necessary to remove the very fine portion of the powders. The very fine materials that are less than 325 mesh are able to migrate in between the various pieces of the assembled die and contaminate the PbTe powders. A suitable particle size distribution is −140+325 mesh.

### Copper Bonding Layer

The thermoelectric elements that result from the layering process are then assembled into an eggcrate structure that holds the legs in a checker board pattern so that all N legs have only P leg neighbours and all P legs have only N leg neighbors. The hot end of a P leg is then electrically connected to the hot end of the adjacent N leg. To make a good low resistance connection it is preferable to use a copper conductor but while copper will bond to iron it does not form a strong enough bond to withstand normal handling and will often fail due to thermal expansion differences alone. If a copper bond layer is built into the hot end of the leg then copper can easily be diffusion bonded to the leg and a strong low resistance bond can be formed. The copper bonding layer is formed by sand blasting a piece of copper foil 0.020″ thick and placing it in the die on top of the top layer of Fe powder. During the sintering operation the copper foil will form a bond with the Fe powder. The bond can be further enhanced by allowing a burr to form on the edge of the copper during the punching operation and the burr will help to anchor the Cu into the iron powder. An alternative method of forming the copper bonding layer is to add a layer of Copper powder on top of the hot end Fe layer. If this method is used it is extremely important to not allow any Cu dust to mix with the PbTe or to react with the Mo die. Good mold release agents such as WS₂ will help to prevent this reaction.

### Dual Egg-Crate Construction

An eggcrate is used to:
fix each leg in the desired location,
allow the formation of electrical connectors by thermal spray metallizing the surface of the loaded eggcrate and then sanding down the surface of the deposited metal until the eggcrate wall is exposed
prevent vapor phase transport of the Te and/or PbTe from the P leg to the N leg or vice versa.

For applications that do not exceed 300° C. an eggcrate can be inexpensively fabricated from high temperature polymers such as liquid crystal polymers or polyimide but for temperatures exceeding 300° C. the eggcrate must be fabricated from glasses or ceramics. Ceramic eggcrates are discussed in earlier Hi-Z patents but one low cost variation to a ceramic eggcrate or a two part polymer/ceramic eggcrate is to use a polymer eggcrate on the cold side of the module to locate the thermoelectric elements and to allow the formation of the cold side conductors by metallizing the module and then fill the hot space between the hot side of the legs with a castable ceramic. The castable ceramic will help support and strengthen the legs and it will prevent transport of the Te and/or PbTe from one leg to the other. The hot side conductors can then be formed by metallizing through a mask or through some other process.

An alternative to using ceramics to form the hot side of the two part egg-crate is to use mica to form the hot side egg-crate. This could be done in a manner similar to the egg-crate discussed in the background section of this specification but only the hot half of the egg-crate is formed using that process and the cold side of the egg-crate is formed using and injection molded polymer such as Zenite.

In preferred embodiments, the high-temperature ceramic (preferably Resbond 989 or Resbond 908) available as a high-temperature, general purpose ceramic adhesive from Cotronix Corporation, and the liquid crystal polymer material (preferably Zenite) available from DuPont in the form of a liquid crystal polymer resin.

### Bonding Copper Hot Side Conductors

Copper conductors are bonded to the copper bonding layer on the hot end of the legs by fixing the copper conductors to the hot side module in the desired location using an adhesive that will vaporize away at temperatures above 300° C. The module with the hot side conductors is then placed in between a heater and a chilled plate under a force of 500 psi in a chamber where the atmosphere can be controlled. In a reducing atmosphere the hot side of the module is heated to 575° C. and held until the resistance of the module drops to below 500 mΩ. This usually happens in less than two hours.

### Alternative P Leg

In the above description of the first preferred embodiment the cold side of the P leg is made from a Bi₂Te₃ alloy and the hot side of the leg is made from a PbTe alloy. As described in Table 2 a layer of PbTe powder is placed in the die and a layer of Bi₂Te₃ powder is placed on top of the PbTe powder and the two powders are sintered in a vacuum at 500° C. under a pressure of 6,000 psi. Pressing the Bi₂Te₃ powder in this manner will cause the grains to orient in a direction that will yield non-optimum properties for the Bi₂Te₃ portion of the leg. However, the properties of the Bi₂Te₃ portion are still far superior to a P leg as compared to using only PbTe for the cold portion of the leg.

A Bi₂Te₃ segment with better properties can be obtained by pressing a B₂Te₃ leg in a separate step by cutting a leg segment from a cast Bridgeman ingot in such a way that the ideal properties are oriented to be parallel with the pressing direction and then placing PbTe powder on top of the prefabricated Bi₂Te₃ segment. The Bi₂Te₃ leg segment must be a snug fit with the die to prevent the grains from rotating during the vacuum hot pressing operation.

### Lubricant

When vacuum hot pressing PbTe legs it is important to use a lubricant to:
prevent the components of the thermoelectric leg from reacting with the die.
allow the part to be easily removed from the die.

Some of the better mold release agents are MoS₂ and WS₂.

### Hermetic Seal

In order for a thermoelectric module containing PbTe to last more than a few thousand hours it must be contained in a reducing environment with a hermetic seal that will prevent transmission of any oxygen through the seal. A hermetic seal of this quality can not be obtained using organic materials and must be made with metals, ceramics or glasses. One method of doing this is to thermal spray the entire module with an insulating material such as alumina and then to spray a layer of stainless steel on top of the ceramic. The metal coating will contain small pinholes that can then be sealed by melting the metal surface with a laser. The space inside the module can be made to be reducing by dispersing silicon particles inside the castable ceramic.

An alternative method that has been shown to be promising is to powder coat the module with a high temperature powder coating paint such as Eastman's HotCoat High-Temp powders. These paints are based on silicone and when exposed to high temperatures the silicone is converted to glass. Several layers may be necessary to obtain a complete seal. Other forms of high temperature paints could be used by powder coating paints can obtain a more uniform coating with better integrity.

To further improve the seal created by the powder coated paint an additional metal layer can be added by thermal spraying or by electroplating and/or electroforming.

### Technique to Prevent Te Evaporation and Contamination

As indicated in the background section life testing of PbTe modules by Applicants has shown that some degradation of the module occurs after approximately 1,000 hours of operation. Applicants have discovered that the degradation can be attributed to “cross-talk” between the N legs and the P legs near the hot junction caused by evaporation of tellurium from the P leg contaminating the N leg. (As explained in the background section an excess of lead in the N leg is what provides the n-leg with some of its thermoelectric doping properties and an excess of Te in the P leg provides the P leg with some of its thermoelectricity.) The problem is prevented in preferred embodiments with two techniques: First, the egg-crate walls separating the N legs from the P legs may be extended to contact the hot conductor so that tellurium vapor is restrained from migrating to the n-leg. A second technique used by Applicants is to add a thin layer of PbSnMnTe at the top (hot side) of the p-legs (not shown in the drawings). Applicants have determined that elemental tellurium exhibits little or no evaporation from PbSnMnTe. While the PbSnMnTe material does not have as good thermoelectric properties as PbTe, the amount used is small, only 0.020 inch long out of 0.450 inch overall length. The PbSnMnTe segments will be vacuum hot-pressed and sintered with the 2P type PbTe and Bi₂Te₃. In some embodiments the PbSnMnTe material may be substituted for the hot portion of the p-legs.

With the use of a hot side egg-crate the hot side conductors can be formed using thermal spray metallization. Thermal spraying the hot side conductors does a good job of sealing the hot side of the legs thereby hindering the diffusion of Te vapors from one cavity to another.

### Techniques to Better Orient the Bi₂Te₃ Segments

Some other techniques to better orient the Bi₂Te₃ Segments are described below:

### Press, Separate and Bond

This method consists of the following steps:
1) Press and sinter the PbTe segment.
2) Press and sinter the Bi₂Te₃ segment.
3) Rotate the Bi₂Te₃ segment so that it's best properties (perpendicular to the pressing direction) are in the correct orientation and insert the segment into a tight fitting die. If the die allows the Bi₂Te₃ segment to deform an excessive amount the grains will rotate and the properties will be degraded.
4) Insert the PbTe segment so it rests snuggly against the Bi₂Te₃ segment. It may be useful to use an interface layer to aid in the bonding. One potential interface layer is SnTe.
5) Sinter the combined segments at 500° C. in a reducing atmosphere for 48 hours.
1) ing atmosphere for 48 hours.
And alternative to this method would be to:
1) Press and sinter the Bi₂Te₃ segment.
2) Rotate the Bi₂Te₃ segment so that it's best properties (perpendicular to the pressing direction) are in the correct orientation and insert the segment into a tight fitting die. If the die allows the Bi₂Te₃ segment to deform an excessive amount, the grains will rotate and the electrical properties will be degraded.
3) Fill the remainder of the die with PbTe powder. An interface layer such as SnTe may be useful.
4) Cold press and sinter the resultant element or the element could be hot pressed.

### Press, Separate and then Co-Press

During the pressing operation, N type Bi₂Te₃ grains become oriented in the plane perpendicular to the pressing direction. To make a useful pressed N type Bi₂Te₃ leg, the leg must be used so that the temperature gradient is perpendicular to the pressing direction of the element. While this is simple to do with an un-segmented leg it is difficult to do this with a segmented leg because the powders from the two segments will tend to mix in the die and an accurate segment line will be difficult to achieve. The disclosed method consists of pressing the two segments into low density blocks that contain the proper amount of material for the desired final segments and then inserting these pre-pressed blocks into a die that will be subsequently pressed perpendicular to the expected temperature gradient. The Bi₂Te₃ segment and the PbTe segment may be two separate pieces as shown in FIG. 9, or a single piece as shown in FIG. 10 and as described below:
1) Separately cold press the PbTe and the Bi₂Te₃ segments. The pellets should be of low density and each segment should have the proper amount of material for the final leg. The two segments should be of a geometry small enough to fit into the die that will be used for the final press.
2) Place the segments (either one piece or two pieces) side-by-side into a die that has the desired final geometry.
3) Press the pellet to the desired density. Because the pellet has a low density and because the die is larger than the pellet, the pellet will under go significant deformation during this second pressing operation. As the Bi₂Te₃ segment is pressed the movement caused by the punch will cause the Bi₂Te₃ grains to rotate into the desired orientation and result in optimum properties in the same direction as the intended temperature gradient. The die must be close to the same size as the pellet being pressed or the segment line will be too distorted.
4) Sinter the combined segments elements at 500° C. for 48 hours.

### Three Segment P-Legs and Two Segment N-Legs

A preferred alternative of the present invention is similar to the first preferred embodiment. It combines the above techniques with existing state of the art materials to produce a cost effective thermoelectric module with an accumulated efficiency of 16 percent when operated between a hot side temperature of about 560° C. and 50° C. The stack-up of improved efficiencies is shown in Table 3. Conventional available PbTe materials can provide modules with efficiencies of 7 percent with the above temperature difference. In this preferred embodiment Applicants increase the efficiency to 9 percent by adding a P-type Bi₂Teₐ cold segment and further increase the efficiency to 10 percent by adding an N-type cold segment using a new Bi₂Te₃ material developed by Applicants. The efficiency is further increased to 11 percent by dividing the PbTe material into two segments, i.e. 2P and 3P. An improved PbTe material is used to gain another incremental improvement in efficiency to 12 percent as described in U.S. patent application Ser. No. 12/293,170 which is incorporated by reference herein. Utilizing nano-grained Bi₂Te₃ available from GMZ Inc., with offices in Waltham, Mass., provides another 1.0 percent to increase the accumulated efficiency to 13 percent and finally an additional 3 percent improvement is provided by use of nano-grained PbTe material to provide a module that operates at efficiencies of about 16 percent.

TABLE 3
Approaches to Improving Module Efficiency

| | Technology | Digit Increase | Accum. |
|---|---|---|---|
| Approach | status | in efficiency | Efficiency |
| Commercially | Hi-Z fabricates | — | 7% |
| available PbTe | | | |
| P type Bi₂Te₃ | existing | 2% | 9% |
| cold segment | | | |
| N type Bi₂Te₃ | new | 1% | 10% |
| cold segment | | | |
| 2P with 3P hot segment | new/existing | 1% | 11% |
| Vendor X, N type PbTe | new | 1% | 12% |
| Nanograined Bi₂Te₃ | existing | 1% | 13% |
| from GMZ Inc. | | | |
| Nanograined PbTe legs | new | 3% | 16% |

### Alternate Bulk Alloys

Lead telluride based alloys have been used since the 1960s and the alloys and recommended doping levels were documented above. Their thermoelectric properties versus temperature are given in many publications such as Chapter 10, “Lead Telluride Alloys and Junctions” of Thermoelectric Materials and Devices, Cadoff and Miller, published by Reinhold Publishing Corporation of New York.

In the past four years newer PbTe based alloys have evolved that have better properties than the conventional PbTe based alloys noted above. For example a Jul. 25, 2008 article in Science Daily reported on a lead telluride material developed at Ohio State University having substantial improvements in efficiency over prior art lead telluride materials. This new material is doped with thallium instead of sodium. The article suggests that the efficiency of the new material may be twice the efficiency of prior art lead telluride. Other experimenters have developed a new N type PbTe which is doped with Ti and iodine and has a ZT of 1.7 (PbTe is typically about 1.0). The P type alloy is Pb₇Te₃ and doped with AgTe. While it has the same ZT as PbTe 2P its advantage is that it can be used with Fe hot shoes segmented to Bi₂Te₃ alloys.

Applicants are seeking to prepare bulk lead telluride thermoelectric material with a finer grain size than has previously been achieved. Fine grain size is expected to lower the thermal conductivity of the material without significant impact on resistivity or Seebeck coefficient, thus raising its ZT and efficiency. In previous attempts others have made to produce a fine-grained PbTe, the grain size was observed to coarsen rapidly, even near room temperature, so the benefit of small grain size could not be retained. In this study, Applicants seek to preserve a fine grain structure by additions of very fine alumina powder, which is expected to produce a grain boundary pinning effect, thus stabilizing the fine grain size. Applicants' recent results indicate that the PbTe grain size can indeed be held below 2 μm, even with processing at 800° C.

### Lead Telluride Only Modules

Some of the techniques described herein can be utilized in modules where the entire legs are comprised of only lead telluride thermoelectric alloys. Preferably, the lead telluride alloy or alloys are one or more of the newer very high efficient alloys.

### Other Thermoelectric Materials

The methods described above for making the first preferred embodiment can be used with respect of many other thermoelectric materials several of which provide better performance especially at the high temperature ranges. So these materials can be stacked and bonded using the above techniques to improve performance. Some of these materials are:

| Alloy | Peak Z | Temperature at Peak Z (k) |
|---|---|---|
| TAGS | 0.0020 | 675 |
| Si80Ge20 | 0.0008 | 800 |
| LaTe | 0.0010 | 925 |
| PbTe | 0.0018 | 775 |
| Zintle | 0.0011 | 1,250 |
| Bi2Te3 | 0.0025 | 325 |
| Skkutterudite | 0.0018 | 925 |
| FeSi2 | 0.0002 | 925 |

Since these materials are all strongly temperature dependant they should be combined in such a way that each would operate in its ideal temperature range. For example a good combination would be bismuth telluride at cold temperatures of about 325 K, followed by a segment of TAGS at about 675 K followed by lead telluride at about 775 K and finally a hot side skutterudite segment operating at about 925 K. As described above interface layers could be used to accommodate differences in thermal expansion and additionally interface layers could also be used as diffusion barriers to inhibit reactions between the various layers.

### Generator Design Using PbTe-Type Modules of the Preferred Embodiment

The high-temperature module of the preferred embodiment requires encapsulation to prevent oxidation of the N and P alloys with an accompanying decrease in thermoelectric properties. An example of encapsulating PbTe modules would be the 1 kW generator for diesel trucks shown at 16 in FIG. 5 since all of the modules are encapsulated together encapsulation of the individual modules is not necessary. In this example the generator is attached to a 5-inch diameter exhaust pipe 18. Lead telluride thermoelectric modules 20 are mounted on a support structure 22 which is machined or formed to create an octagon. The inside surface is generally round with fins (not shown) which protrude into the gas stream to provide a greater heat transfer area. The basic design is similar to the design described in U.S. Pat. No. 5,625,245 which is hereby incorporated herein by reference.

The casting of the support structure has two flanges 24 and 26, one large and one small which are perpendicular to the main part of the support structure. The large flange 24 is about 10 inches in diameter while the small flange 26 is about 8 inches in diameter.

The large flange contains feed-throughs for both the two electrical connections and four water connections. The two electric feed-throughs 28 are electrically isolated with alumina insulators from the support structure. Both the large and small flange will contain a weld preparation so a metal dust cover 30 can be welded in position.

The four water feed-through elements 32 consists of one inch diameter tubes that are welded into the flange. The inside portion of the water tubes are welded to a wire reinforced metal bellows hose with the other end connected to the heat sink by a compression fitting or a stainless to aluminum bimetallic joint. Two of the tubes are inlets and the other two tubes are outlets for the cooling water.

Once the generator is assembled and the flanges between the support structure and the dust cover are welded as shown at 34, the interior volume will be evacuated and back filled with an inert gas such as Argon through a small ⅜ inch diameter tube 36 in the dust cover to about 75% of one atmosphere when at normal room temperature (˜20° c.). Once filled, the fill tube will be pinched off and welded.

In a preferred embodiment nine thermoelectric modules 20 of the first preferred embodiment are mounted on each of the eight sides of the hexagonal structure for a total of 96 modules. Applicants estimate a total electrical output of about 1.1 kilowatts. This estimate is based on prior performance with the structure described in the U.S. Pat. No. 5,625,245, utilizing modules of the first preferred embodiment and assuming an exhaust hot side temperature of about 550° C. and cold side cooling water temperature of about 100° C.

### Module Encapsulation

An alternative to encapsulation of the entire generator, as shown in FIG. 5A and FIG. 11, is to encapsulate the individual modules. FIG. 5B shows such a technique. This is an example where the module is encapsulated in a thin metal capsule which is comprised of a bottom plate and a cover. The two parts are welded at the seam. The metal capsule requires a thin insulating sheet on both the hot side and the cold side. Capsules can also be formed with insulating material such as SiO₂.

### Molded Egg-Crate with Legs in Place

An alternative technique for making the thermoelectric module of the present invention is molding the egg-crate with the thermoelectric legs in place.

Thermoelectric egg-crates serve several functions. They hold the elements in the correct locations, they define the pattern of the cold side connectors and they locate the hot side connectors. Egg-crates can be assembled from mica as described in U.S. Pat. No. 4,611,089, injection molded plastic (gapless egg-crate) as described in U.S. Pat. No. 5,875,098 or injection molded ceramic or injection molded plastic and ceramic as described in parent application Ser. No. 12/317,170. An alternative method of fabricating the egg-crate is proposed below:
1) A two-part mold is fabricated from a suitable material. Some possible mold materials are polyethylene, aluminum or Teflon. The mold is designed to hold the thermoelectric elements in place while a mold material is poured around the elements.
2) Thermoelectric elements are loaded into the top half of the mold assuring that the N and P elements are located appropriately as shown in FIG. 11A.
3) The bottom half of the mold is put in place and castable material is poured into the mold filling the spaces labeled “cast material”. Several choices are available for suitable castable materials. A two part epoxy would be suitable for low temperature applications. For high temperature applications Aremco's Ceramacast 584 or 645-N would be a good choice.
4) After the mold material has cured the part is removed from the mold.
5) The cast egg-crate containing the thermoelectric elements is then ready to have the cold side contacts made as described in U.S. Pat. No. 5,875,098. The loaded egg-crate is then fixtured appropriately to hold the elements in place while aluminum with a proper molybdenum bond coat is thermally sprayed onto the cold (bismuth telluride) side of the module. This process is explained in detail in U.S. Pat. No. 4,611,089. An alternative metal to Mo/Al combination is zinc.

Unlike the gapless egg-crate modules described in U.S. Pat. No. 5,875,098, only the cold side of the segmented module is connected in this manner. With the module held firmly to prevent warping, the deposited coating (Mo, Al or zinc) is sanded to expose the egg-crate walls which thereby define the cold side electrical connectors as described in U.S. Pat. No. 5,875,098. The module is then lapped to a suitable finish and the bottom (cold side). Copper shoes provide the hot side electrical connections.

Using a slightly different mold design, a high temperature mold material could be used for the hot side of the module and a low thermal conductivity material could be used for the cold side as suggested by the dashed line in FIG. 11D. Ideally, a two part egg-crate with the cold side being a polymer/organic based material for strength and the hot side being a ceramic based material for high temperature resistance would be the best choice.

### Preferred Module

An example of a module that incorporates the features described above will have the following properties:

| | | |
|---|---|---|
| Module width | 5.0 | cm |
| Module depth | 5.0 | cm |
| Module thickness | 1.0 | cm |
| Hot side temperature | 560° | C. |
| Cold side Temperature | 60° | C. |

The thermoelectric legs used in the preferred embodiment are 7.0 mm long but only 5 mm of that length is active thermoelectric material. Each end of the leg, with the exception of the cold side of the P leg, will consist of 0.5 mm of Fe and 0.5 mm of a transition material consisting of 25% Fe and 75% PbTe. The cold side of the P leg will consist of 1 mm of 90% Fe and 10% Bi₂Te₃.

The 32 P type legs—each P leg is 7.0 mm long, 5.0 mm wide and 5.0 mm deep. The bottom (cold side) 2.2 mm is bismuth telluride and the top 2.8 mm is 2P.

The 32 N type legs—each N leg is 7.0 mm long, 5.0 mm wide and 5.0 mm deep. The bottom (cold side) 3.8 mm is 2N and the top 1.2 mm is 3N.

Knowing the thermal conductivity of the thermoelectric alloys and how it changes with temperature gradient along the length of the leg is calculated and the segment line for each thermoelectric alloy is positioned as indicated in FIGS. 6A and 6B. According to these figures the Bi₂Te₃ segment on the N leg would be positioned so that its center is at 300° C. The 3N segment on the hot side on the N leg should be positioned so that its center is at 420° C. The 3P segment on the hot side of the P leg is there to avoid Te vaporization so it should be made as thin as possible and still form a reliable separation between the 2P material and the iron shoe. Preferably that thickness is about 1 mm.

Performance specifications are as follows:

| | | |
|---|---|---|
| Power | 27 | watts |
| Open circuit voltage | 6.0 | volts |
| Voltage at matched load | 3.0 | volts |
| Heat flux | 15 | W/cm² |
| Internal resistance | 0.33 | ohms |

| | |
|---|---|
| Efficiency (max) | 10% |

### Variations

While the above description contains many specificities, the reader should not construe these as limitations on the scope of the invention, but merely as exemplifications of preferred embodiments thereof. For example:

### Other High Temperature Thermoelectric Alloys

Some of the other thermoelectric alloys that are attractive over high-temperature ranges are:
Si-20% Ge, LaTe_{1.4} type alloys
Zintl, (Yb₁₄MnSb₁₁)
TAGS (AgSbTe₂)_{0.15}(GeTe)_{0.85}
The skutterudites such as CoSb₄ type alloys
The half-Huesler alloys

### The LAST and FAST Alloys of Michigan State University

All of these bulk alloys and others under development can be used in the new ZrO2/Zenite egg-crate design described in the parent applications that has been incorporated by reference herein or the other eggcrate designs that are described herein.

### Other Fabrication Techniques

### Segmented Legs

Separate portions of the segmented legs can be readily bonded together by passing a current through both using a spot welding machine sometimes also referred to as spark sintering. As the current passes through the samples, the interface, which is purposely made to have a high resistance, reach a temperature at which bonding takes place. Sometimes a liquid phase is formed. The spot welding time is only a fraction of a second. To form a consistent bond, wire mesh has been used. The mesh preferentially heats up and imbeds itself in both materials. The N type Bi₂Te₃, which must be used in the correct orientation, retained its crystalline orientation and was successfully bonded to N type PbTe. The contact resistance between the two components was less than 100 μΩ-cm² and the bond was strong. This bonding technique was also successful for bonding the P leg PbTe and Bi₂Te₃ segments.

The PbTe portions of the p-legs can also be cold pressed and sintered separately from the Bi₂Te₃ portions. When they are subject to hot operating conditions they will diffusion bond. The same applies to the n-legs.

### Hot Pressing of the Legs

Another option is to hot press the thermoelectric materials in bulk then slice and dice them into legs.

### Tape Casting

An alternative method to forming the legs is to cast each of the desired materials into a fugitive binder and form thin sheets of the material called “tape”. In this manner a large die can be filled with various stacked tapes containing the desired materials. The tape is filled with a known amount of the desired powder so that when the tape is heated and pressed in a vacuum the binder is driven off and the correct amount of powder remains behind to form a layer of the material that has the desired thickness. For example a large die could be filled with first a tape containing Fe powder and then a tape containing mixed Fe and PbTe powders with about 75 weight percent PbTe and 25% Fe and then one or more tapes containing PbTe powder and then a second layer of mixed Fe and PbTe powders and finally a second layer of tape containing Fe powder. The entire stack up of tapes are then forced in a Mo die and pressed to 6,000 psi while in a vacuum and heated to 600° C. for one hour. The Fe and mixed powders would each contain enough powder to result in a layer about 0.5 mm thick and the PbTe layer(s) would result in about 5 mm of PbTe. The final product will be a slab of material about 7 mm thick. The slab is then cut into rectangles that are 5 mm square that have the original thickness of the slab.

Important to the success of this approach is selection of the fugitive binder. The only products that we know will work are a line of products based on the polymerization of carbon dioxide called QPAC™ made by Empower Materials, Inc. and especially a particular product called “QPAC-40 Low Monomer”. This material can be dissolved in acetone to form a viscous sticky liquid. The powdered materials comprising individual segments or layers of the TE leg can be mixed with this liquid and cast into 2-dimensional forms. When the acetone evaporates, the resulting material is a self-cohesive and flexible solid sheet or “tape”. The critical characteristic of the QPAC is that when heated in vacuum or inert atmosphere, it will thermally decompose below 325° C. and turn completely into carbon dioxide gas, leaving no detectable solid residue intermixed with the powder. The fugitive binder thus functions as a temporary carrier that enables powders of multiple different compositions to be arranged in particular fixed spatial arrangement or configuration within the compaction die until enough pressure can be applied to permanently fix them into their intended final relative positions.

The process called “tape casting” is well known in the field of electronic ceramics, but it is nearly always practiced with materials that can be sintered in air, such as oxide ceramics like alumina. In air-firing systems, acrylic polymers are most commonly chosen binders since they burn away in air leaving negible residues.

### Other Crate Designs

### Aerogel Crate

In one variation, an aerogel material is used to fill all unoccupied spaces in the egg-crate. A module assembly will be sent to an aerogel fabrication laboratory. They will immerse it in silica sol immediately after dropping the pH of the sol. The sol converts to silica gel over the next few days. It is then subjected to a supercritical drying process of tightly controlled temperature and pressure condition in a bath of supercritical liquid CO₂. This process removes all the water in the gel and replaces it with gaseous CO₂. The Aerogel serves multiple functions: (1) helping to hold the module together, (2) reducing the sublimation rate of the PbTe and (3) providing thermal and electrical insulation around the legs.

In another variation, an egg-crate made of non-woven refractory oxide fiber material, possibly with a fugitive polymer binder, and having the consistency of stiff paper or card stock is used. After assembly, the binder is burned away, leaving a porous fiber structure that is them infiltrated with Aerogel. The fiber reinforcement of the aerogel gives added strength and toughness.

Those skilled in the art will envision many other possible variations within its scope. Accordingly, the reader is requested to determine the scope of the invention by the appended claims and their legal equivalents, and not by the examples which have been given.

What is claimed is:

1. A thermoelectric module comprising:
A. a two-part egg-crate for holding in place and providing insulation and electrical connections for a number of thermoelectric N-legs and P-legs, wherein said egg-crate is comprised of:
1) a hot side part comprised of a ceramic material capable of operation at temperatures in excess of 500° C. and
2) a cold side part comprised of a polymeric material having very low thermal conductivity.
B. a plurality of segmented thermoelectric N-legs and P-legs, each leg comprised of at least one PbTe segment and positioned in said egg-crate, at least a portion of said legs being electrically connected in series;
wherein
1) each of at least a plurality of said N-legs are comprised of
a) a high-temperature thermoelectric segment and
b) a low-temperature thermoelectric segment and
2) each of at least a plurality of said P-legs are comprised of
a) a high-temperature thermoelectric segment and
b) a low-temperature thermoelectric segment.

2. The thermoelectric module as in claim 1 wherein at least a plurality of said low-temperature thermoelectric segments of said P legs are comprised of BiTe.

3. The thermoelectric module as in claim 1 wherein at least a plurality of said N and P legs are fabricated utilizing a multi-cavity die having walls adapted for disassembly to permit removal of sintered legs without damage.

4. The thermoelectric module as in claim 3 wherein the die is comprised of molybdenum.

5. The thermoelectric module as in claim 1 wherein each of a plurality of said N-legs also comprises at least one intermediate temperature PbTe segment.

6. The thermoelectric module as in claim 1 wherein N legs are comprised of two types of PbTe and the P legs are comprised of PbTe on the hot side and Bi₂Te₃ on the cold side.

7. The thermoelectric module as in claim 1 wherein iron contacts are vacuum hot pressed along with the thermoelectric materials to create good compatible contact surfaces.

8. The thermoelectric module as in claim 1 where interfaces between the materials are graduated in composition to improve performance.

9. The thermoelectric module as in claim 1 where special techniques are utilized in the leg fabrication process to assure fines are removed.

10. The thermoelectric module as in claim 1 wherein a thin copper binding layer is also added on top of the iron at the hot side of the legs and hot pressed into the leg material.

11. The thermoelectric module as in claim 1 wherein dual egg-crate is provided with high temperature ceramic used at the hot side and low thermal conductivity moldable thermo plastic is used for the cold side.

12. The thermoelectric module as in claim 1 wherein a molybdenum sulfide lubricant is applied to die surfaces in the fabrication of the legs to minimize or eliminate leg damage during removal from the die.

13. The thermoelectric module as in claim 1 wherein the modules are hermetically sealed either individually or as a part of thermoelectric systems.

14. The thermoelectric module as in claim 1 wherein each of a plurality of said P-legs also comprises at least one intermediate temperature PbTe segment.

15. The thermoelectric module as in claim 1 wherein said plurality of said lead-telluride thermoelectric N-legs and P-legs are electrically connected with one or more metals thermally sprayed on at least one side of the module defining a cold side.

16. The thermoelectric module as in claim 15 wherein said one or more metals is zinc.

17. The thermoelectric module as in claim 16 wherein said one or more metals is molybdenum and aluminum.

18. The thermoelectric module as in claim 1 wherein said ceramic material is zirconium oxide and said polymeric material is in the form of a liquid crystal polymer resin.

19. The thermoelectric module as in claim 1 wherein a plurality of said thermoelectric legs comprise fine micron/nano-sized grains.

20. The thermoelectric module as in claim 1 wherein each N-leg and P-leg of at least a plurality of pairs of said thermoelectric N-legs and P-legs are electrically connected utilizing an iron shoe.

21. The thermoelectric module as in claim 1 wherein each N-leg and P-leg of at least a plurality of pairs of said thermoelectric N-legs and P-legs are electrically connected utilizing a copper strip.

22. The thermoelectric module as in claim 15 wherein the egg-crate walls separating the n-legs from the p-legs are adapted to contact the hot conductor so that tellurium vapor is restrained from migrating to the n-leg.

23. The thermoelectric module as in claim 7 wherein at least a plurality of the P-legs comprise a thin layer of PbSnMnTe at their hot sides.

24. The thermoelectric module as in claim 7 wherein at least a plurality of the P-legs comprise a thin layer of PbSnTe at their hot sides.

25. The thermoelectric module as in claim 7 wherein at least a plurality of the P-legs comprise a thin layer of SnTe at their hot sides.
